(19) United States
(12) Patent Application Publication
(10) Pub. No.: US 2013/0207190 A1
(43) Pub. Date: Aug. 15, 2013

(54) SEMICONDUCTOR DEVICE, AND METHOD FOR PRODUCING SAME

(71) Applicant: Hiroyuki Kaigawa, Osaka (JP)

(72) Inventor: Hiroyuki Kaigawa, Osaka (JP)

(73) Assignee: SHARP KABUSHIKI KAISHA, Osaka (JP)

(21) Appl. No.: 13/879,231

(22) PCT Filed: Oct. 31, 2011
(86) PCT No.: PCT/JP2011/075056

§ 371 Date: Apr. 12, 2013

(30) Foreign Application Priority Data
Nov. 4, 2010 (JP) 2010-247037

(51) Int. Cl. H01L 27/12

(52) U.S. Cl. CPC H01L 27/1211
USPC 257/347; 438/151

(57) ABSTRACT

Disclosed is a semiconductor device 100 including a substrate 1, a thin film diode 10A that is supported by the substrate 1 and that includes a first semiconductor layer 13a having a p-type region 13a(p) and an n-type region 13a(n), a first wiring line RST disposed so as to overlap with the first semiconductor layer 13a of the thin film diode 10A and connected to the p-type region 13a(p), a second wiring line RWS disposed so as to overlap with the first semiconductor layer 13a of the thin film diode 10A and connected to the n-type region 13a(n), and a thin film transistor 10B that is supported by the substrate 1 that includes a second semiconductor layer 13b, a gate electrode, a source electrode, and a drain electrode. The first wiring line RST and the second wiring line RWS are formed of the same conductive film 15 as the gate electrode.

### TECHNICAL FIELD

The present invention relates to a semiconductor device provided with thin film diodes (TFDs), and to a method of manufacturing the same, and more particularly, to a display device provided with photosensor sections that use the TFDs, and to a method of manufacturing the same.

### BACKGROUND ART

In recent years, semiconductor devices such as a display device or an image sensor provided with photosensor sections that have TFDs have been developed. Patent Document 1, for example, discloses a liquid crystal display device provided with photosensor sections that have TFDs and a display section that has thin film transistors (TFT) connected to pixel electrodes. According to the technology described in Patent Document 1, semiconductor layers of the TFD and the TFT can be optimized to achieve device characteristics respectively required or the TFD and the TFT.

Although it is important to improve the device characteristics of the TFT and the TFD, as described in Patent Document 1, in display devices and image sensors in particular, improvement in a pixel aperture ratio (the proportion of the area that can be used for display or image sensing) is sought after. Patent Document 1 is hereby incorporated by reference in its entirety.

### RELATED ART DOCUMENT

### Patent Document

Patent Document 1: WO 2009/144915

### SUMMARY OF THE INVENTION

### Problems to be Solved by the Invention

The present invention was made in view of the above situation, and is aiming at reducing the proportion of an area occupied by a photosensor section in a semiconductor device that has a thin film transistor and a thin film diode on the same substrate.

### Means for Solving the Problems

A semiconductor device of the present invention includes: a substrate; a thin film diode supported by the substrate, the thin film diode having a first semiconductor layer that has a p-type region and an n-type region; a first wiring line disposed so as to overlap with the first semiconductor layer of the thin film diode, the first wiring line being connected to the p-type region; a second wiring line disposed so as to overlap with the first semiconductor layer of the thin film diode, the second wiring line being connected to the n-type region; and a thin film transistor supported by the substrate, the thin film transistor having a second semiconductor layer, a gate electrode, a source electrode, and a drain electrode, wherein the first wiring line and the second wiring line are formed of the same conductive film as the gate electrode.

In one embodiment, the first semiconductor layer and the second semiconductor layer are formed of the same semiconductor film.

In one embodiment, the gate electrode is formed on the second semiconductor layer. That is, in one embodiment, the thin film transistor is of a staggered type (a top gate type).

A method of manufacturing a semiconductor device according to the present invention includes: (a) preparing a substrate; (b) forming a first semiconductor layer and a second semiconductor layer on the substrate; (c) forming an insulating layer that covers the first semiconductor layer and the second semiconductor layer; (d) implanting an impurity into the first semiconductor layer to form a p-type region and an n-type region; (e) forming a contact hole in the insulating layer; (f) forming, on the insulating layer, a conductive layer including a first wiring line connected to the p-type region, a second wiring line connected to the n-type region, and a gate electrode after the step (e); and (g) forming a source region and a drain region in the second semiconductor layer after the step (f).

In one embodiment, in the step (b) of the manufacturing method, the first semiconductor layer and the second semiconductor layer are formed of the same semiconductor film.

### Effects of the Invention

According to the present invention, it becomes possible to reduce the proportion of an area occupied by a photosensor section in a semiconductor device that has a thin film transistor and a thin film diode on the same substrate.

### BRIEF DESCRIPTION OF THE DRAWINGS

FIG. 1(a) is a schematic plan view that shows a liquid crystal display device 100 according to an embodiment of the present invention. FIG. 1(b) is a schematic cross-sectional view that shows a TFT substrate 100A of the liquid crystal display device 100.

FIGS. 2(a) to 2(e) are schematic cross-sectional views that illustrate a method of manufacturing the liquid crystal display device 100 (steps A1 to A5) of an embodiment of the present invention.

FIGS. 3(a) to 3(d) are schematic cross-sectional views that illustrate the method of manufacturing the liquid crystal display device 100 (steps A6 to A9) of an embodiment of the present invention.

FIGS. 4(a) to 4(d) are schematic plan views that illustrate the method of manufacturing the liquid crystal display device 100 (steps A1, A4, A6, and A9) of an embodiment of the present invention.

FIG. 5 shows a structure of a semiconductor device 200 of a reference example. FIG. 5(a) shows a plan view, and FIG. 5(b) shows a cross-sectional view of a TFT substrate 200A.

FIGS. 6(a) to 6(d) are schematic cross-sectional views that illustrate a method of manufacturing the semiconductor device 200 (steps B1 to B4) of the reference example.

FIGS. 7(a) to 7(c) are schematic cross-sectional views that illustrate the method of manufacturing the semiconductor device 200 (steps B5 to B7) of the reference example.

FIGS. 8(a) to 8(c) are schematic plan views that illustrate the method of manufacturing the semiconductor device 200 (steps B1 to B3) of the reference example.

FIGS. 9(a) and 9(b) are schematic plan views that illustrate the method of manufacturing the semiconductor device 200 (steps B5 and B7) of the reference example.

FIG. 10 is a circuit diagram that illustrates configuration and operation of a photosensor section of the liquid crystal display device 100.

### DETAILED DESCRIPTION OF EMBODIMENTS

Below, a semiconductor device of an embodiment of the present invention will be explained with reference to drawings; however, the present invention is not limited to the embodiment that will be illustrated as an example. A liquid crystal display device or a TFT substrate is described as an example of the semiconductor device below.

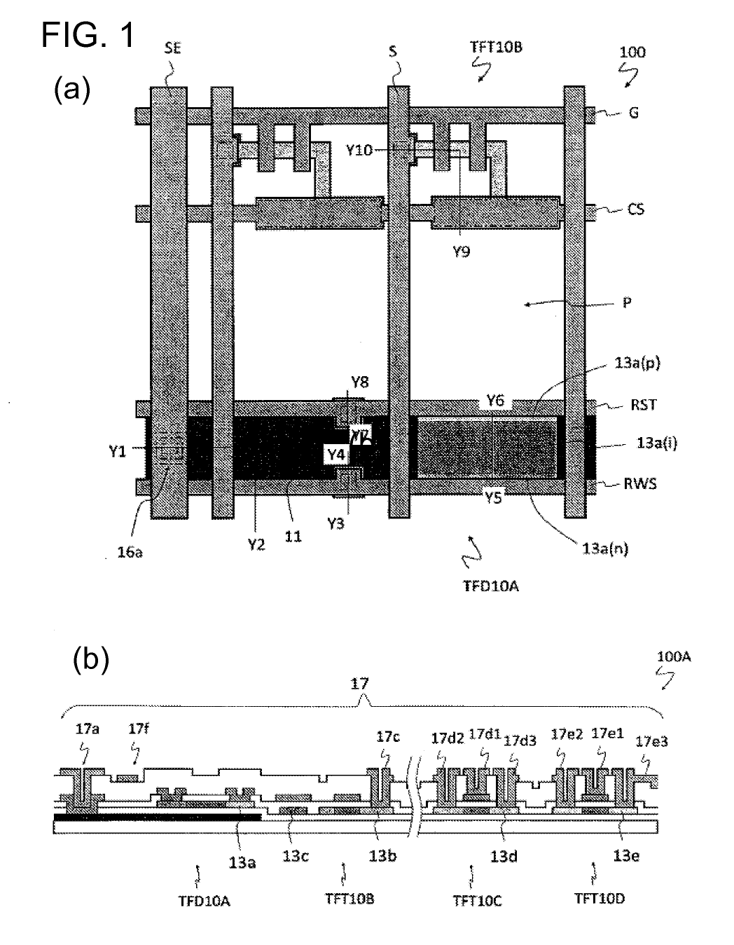

First, a structure of a liquid crystal display device 100 having a touch panel function according to the embodiment of the present invention will be explained with reference to FIGS. 1(a) and 1(b). FIG. 1(a) is a schematic plan view of the liquid crystal display device 100 and FIG. 1(b) is a schematic cross-sectional view that shows a TFT substrate 100A of the liquid crystal display device 100. The cross-sections shown in FIG. 1(b) are cross-sections along the cutoff lines Y1 to Y10 of the corresponding FIG. 1(a), showing a cross-section along the line Y1-Y2, a cross-section along the line Y3-Y4, a cross-section along the line Y5-Y6, a cross-section along the line Y7-Y8, and a cross-section along the line Y9-Y10 in this order from left to right in FIG. 1(b). The TFT substrate 100A has an n-channel TFT 10C and a p-channel TFT 10D for a driver circuit of the liquid crystal display device 100, and FIG. 1(b) also shows cross-sectional structures of the TFTs 10C and 10D.

FIG. 1(a) shows a structure of two adjacent pixels P, which are arranged in a row direction (the direction in which a gate bus line G extends, typically a horizontal direction), of a plurality of pixels P arranged in a matrix. The liquid crystal display device 100 typically has the TFT substrate 100A, an opposite substrate (not shown), and a liquid crystal layer (not shown) disposed between the TFT substrate 100A and the opposite substrate (not shown). The TFT substrate 100A has a pixel electrode (not shown) connected to a drain electrode of a TFT 10B, and the opposite substrate has an opposite electrode disposed so as to face the pixel electrodes via the liquid crystal layer. A structure in which pixel electrodes and an opposite electrode are formed in a TFT substrate 100A such as an IPS mode or an FFS mode is also known. The liquid crystal display device of the embodiment of the present invention is applicable to various modes of liquid crystal display devices, as readily apparent to a person having ordinary skill in the art. Therefore, descriptions of an arrangement of pixel electrodes and an opposite electrode, a liquid crystal layer, an alignment film, a color filter layer, and the like are omitted.

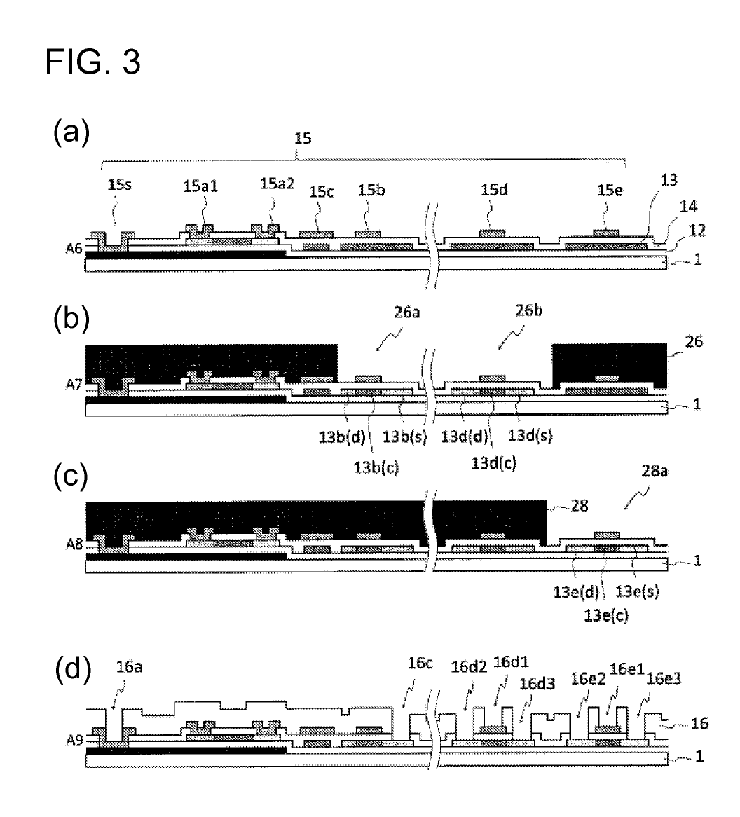

As shown in FIGS. 1(a) and 1(b), the TFT substrate 100A of the liquid crystal display device 100 has a substrate 1, a TFD 10A that is supported by the substrate 1 and that includes a first semiconductor layer 13a having a p-type region 13a(p) and an n-type region 13a(n), a first wiring line RST disposed so as to overlap with the first semiconductor layer 13a of the TFD 10A and connected to the p-type region 13a(p), a second wiring line RWS disposed so as to overlap with the first semiconductor layer 13a of the TFD 10A and connected to the n-type region 13a(n), a TFT 10B that is supported by the substrate 1 and that includes a second semiconductor layer 13b, a gate electrode, a source electrode, and a drain electrode. The first wiring line RST and the second wiring line RWS are formed of the same conductive film as the gate electrode (the gate metal layer 15 in FIG. 3(a)). The TFTs 10C and 10D in FIG. 1(b) will be later described.

As illustrated, it is preferable that the first semiconductor layer 13a and the second semiconductor layer 13b be formed of the same semiconductor film. From the perspective of the TFT characteristics, it is preferable to use a crystalline semiconductor film, and a low temperature polysilicon film or a CG silicon film can be used, for example. The TFT 10B is a staggered type (a top gate type) TFT, and the gate electrode of the TFT 10B is formed over the second semiconductor layer 13b.

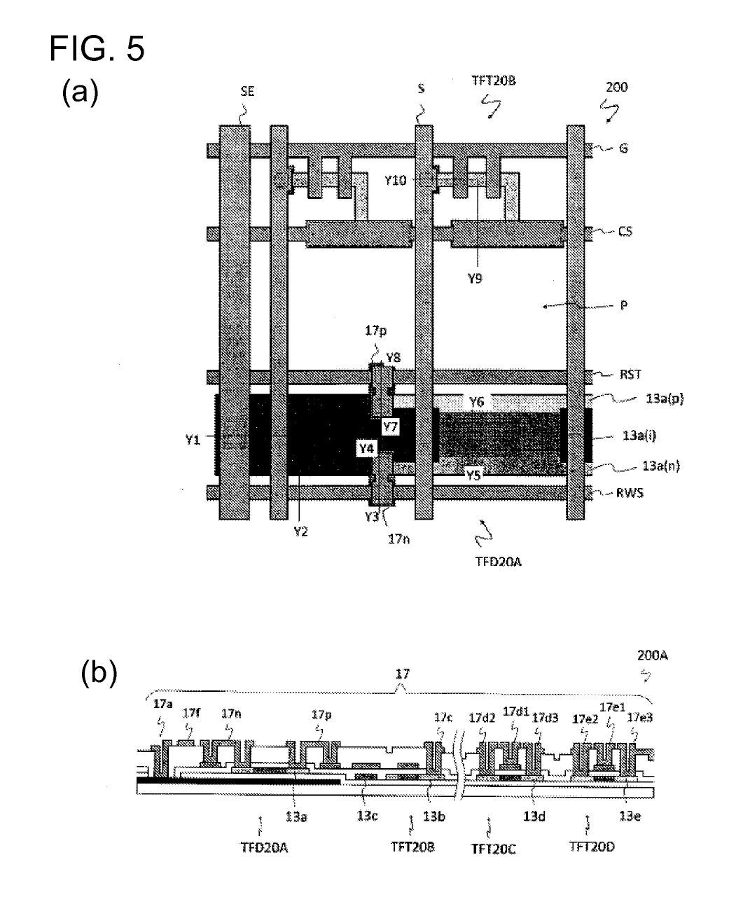

As described above, the liquid crystal display device 100 is configured such that the first wiring line RST and the second wiring line RWS overlap with the first semiconductor layer 13a. Therefore, the proportion of the area occupied by the photosensor section in the pixel P is smaller and the pixel aperture ratio is higher as compared with a liquid crystal display device 200 of the reference example that will be described with reference to the FIG. 5 and the like. For example, in a case of 3.5-inch WVGA (800×480, where a color display pixel constituted of three pixels of R, G, and B is one unit), if one pixel is 120 μm×40 μm and the widths of the first wiring line and the second wiring line (RST and RWS) are approximately 5 μm, respectively, the pixel aperture ratio of the liquid crystal display device 100 is approximately 4% higher than the pixel aperture ratio of the liquid crystal display device 200. The photosensor section is a region surrounded by the first wiring line RST, the second wiring line RWS, and two source bus lines S.

In this embodiment, a PIN diode is described as an example of the TFD 10A. That is, the TFD 10A has an intrinsic region (i region) 13a(i) between the p-type region 13a(p) and the n-type region 13a(n). A PN diode can be used instead of the PIN diode. PIN diode and PN diode detect light radiated to the p-n junction of a semiconductor layer to which a reverse bias voltage is applied by using a flow of excited carriers, which are electrons or holes, in a depletion layer. The PIN diode has an intrinsic region that has high electrical resistance between the p-type region and the n-type region, and thus, the width of the depletion layer that is formed when the reverse voltage is applied is greater, and the flow of the carriers is facilitated by a high electric field generated in the depletion region. Therefore, the PIN diode has advantages that higher light sensitivity and higher response speed can be achieved compared to the PN diode. Furthermore, it is also possible to use a so-called gate-controlled PIN diode in which a gate electrode is formed above the intrinsic region of the PIN diode, and by applying a gate voltage, a reverse dark current that flows through the intrinsic region is reduced.

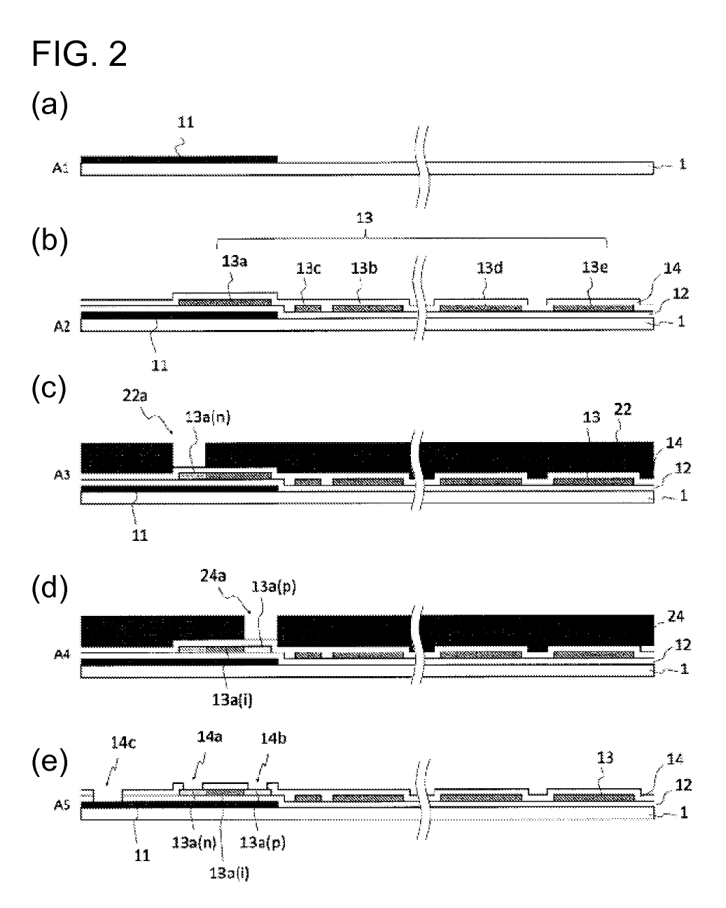

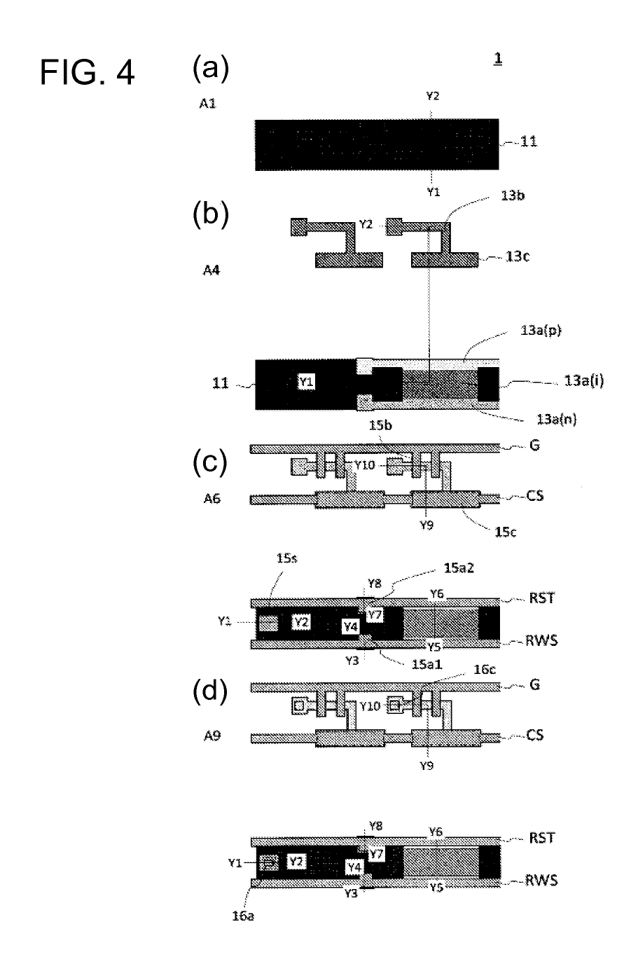

Next, a manufacturing method of the TFT substrate 100A of the embodiment will be described with reference to FIGS. 2 to 4. FIGS. 2 and 3 show schematic cross-sectional views and FIG. 4 shows schematic plan views. Cross-sections in FIGS. 2 and 3 are the cross-sections along the cutoff lines Y1 to Y10 of FIG. 4 that corresponds thereto, showing a cross-section along the line Y1-Y2, a cross-section along the line Y3-Y4, a cross-section along the line Y5-Y6, a cross-section along the line Y7-Y8, and a cross-section along the line Y9-Y10 in this order from left to right of each cross-sectional view. The TFT substrate 100A has the n-channel TFT 10C and the p-channel TFT 10D for a driver circuit of the liquid crystal display device 100, and in FIGS. 2 and 3, manufacturing processes of the TFTs 10C and 10D are also shown. While the TFD 10A and the TFT 10B are formed within a display region constituted of pixels arranged in a matrix, the TFTs 10C and 10D are formed in a peripheral region (also called a frame region), which is outside of the display region.

First, as shown in FIGS. 2(a) and 4(a), a substrate (a glass substrate, for example) 1 is prepared, and a light-shielding layer 11 is formed on the substrate 1 (step A1). The light-shielding layer 11 is formed of a metal film such as a molybdenum film that is 50 nm to 150 nm thick, for example.

Next, as shown in FIG. 2(b), an insulating film 12 is formed over almost the entire surface of the substrate 1, and after forming semiconductor layers 13 on the insulating film 12, a gate insulating film 14 is formed so as to cover the semiconductor layers 13 (step A2). The semiconductor layers 13 are formed by patterning a polysilicon film (30 nm to 70 nm thick, for example) formed so as to cover the almost entire surface of the insulating film 12, for example. The semiconductor layers 13 include the semiconductor layer 13a that becomes an active layer of the TFD 10A, the semiconductor layer 13b that becomes an active layer of the TFT 10B, a semiconductor layer 13c that becomes a lower electrode of an auxiliary capacitance of the pixel P, and semiconductor layers 13d and 13e that become active layers of the TFTs 10C and 10D. The insulating film 12 is formed of a silicon oxide film that is 50 nm to 100 nm thick, for example.

Next, as shown in FIG. 2(c), a resist mask 22 is formed so as to cover the gate insulating film 14 and so as to have an opening 22a that selectively exposes only a portion of the semiconductor layer 13a that becomes the n-type region 13a(n), and an n-type impurity (phosphorus, for example) is implanted by ion implantation (step A3). As a result, the n-type region 13a(n) is formed in the semiconductor layer 13a.

Subsequently, after removing the resist mask 22, as shown in FIGS. 2(d) and 4(b), a resist mask 22 is formed so as to cover the gate insulating film 14 and so as to have an opening 24a that selectively exposes only a portion of the semiconductor layer 13a that becomes the p-type region 13a(p), and a p-type impurity (boron, for example) is implanted by ion implantation (step A4). As a result, the p-type region 13a(p) and the intrinsic region 13a(i) are formed in the semiconductor layer 13a.

Next, as shown in FIG. 2(e), contact holes 14a, 14b, and 14c are formed in the gate insulating film 14 (step A5). The contact holes 14a and 14b are provided for connecting the second wiring line RWS and the first wiring line RST to the n-type region 13a(n) and the p-type region 13a(p) of the TFD 10A, respectively. The contact hole 14c is provided for connecting a wiring line SE to the light-shielding layer 11.

Next, as shown in FIGS. 3(a) and 4(c), the gate metal layers 15 including a gate electrode 15b of the TFT 10B are formed. The gate metal layers 15 include an electrode 15a1 (the second wiring line RWS) that is connected to the n-type region 13a(n), an electrode 15a2 (the first wiring line RST) that is connected to the p-type region 13a(p), an upper electrode 15c of the auxiliary capacitance, an auxiliary capacitance wiring line CS, a gate electrode 15d of the TFT 10C, and a gate electrode 15e of the TFT 10D. Each of the gate electrodes is formed integrally with a corresponding gate bus line. Furthermore, the gate metal layers 15 include an electrode 15s for connecting the wiring line SE to the light-shielding layer 11 through the contact hole 14c. The gate metal layer 15 is formed of a metal film such as aluminum, molybdenum, or tungsten that is 200 nm to 400 nm thick, for example.

Next, as shown in FIG. 3(b), a resist mask 26 having an opening 26a that selectively exposes only the semiconductor layer 13b and an opening 26b that selectively exposes only the semiconductor layer 13d is formed, and an n-type impurity (phosphorus, for example) is implanted by ion implantation (step A7). As a result, a drain region 13b(d), a source region 13b(s), and a channel region 13b(c) are formed in the semiconductor layer 13b in a self-aligned manner with respect to the gate electrode 15b, and a drain region 13d(d), a source region 13d(s), and a channel region 13d(c) are formed in the semiconductor layer 13d in a self-aligned manner with respect to the gate electrode 15d.

Subsequently, after removing the resist mask 26, as shown in FIG. 3(c), a resist mask 28 having an opening 28a that selectively exposes only the semiconductor layer 13e is formed, and a p-type impurity (boron, for example) is implanted by ion implantation (step A8). As a result, a drain region 13e(d), a source region 13e(s), and a channel region 13e(c) are formed in the semiconductor layer 13e in a self-aligned manner with respect to the gate electrode 15e.

Next, after removing the resist mask 28, as shown in FIGS. 3(d) and 4(d), an insulating film 16 that covers almost the entire surface of the substrate 1 is formed, and contact holes 16a, 16c, 16d1, 16d2, 16d3, 16e1, 16e2, and 16e3 are formed (step A9). The insulating film 16 is formed of a silicon oxide film or a silicon nitride film that is 200 nm to 600 nm thick, for example.

Thereafter, as shown in FIGS. 1(a) and 1(b), the TFD 10A, the TFT 10B, the TFT 10C, and the TFT 10D are formed in the TFT substrate 100A by patterning a metal film formed over almost the entire surface of the substrate 1. A metal layer 17a is used as the wiring line SE that is connected to the electrode 15s through a contact hole 16a. A metal layer 17f is used as the source bus line S that is connected to the source electrode of the TFT 10B of an adjacent pixel. A metal layer 17c is used as the source electrode of the TFT 10B. Metal layers 17d1, 17d2, and 17d3 are used as the gate electrode, the drain electrode, and the source electrode of the TFT 10C, respectively. Metal layers 17e1, 17e2, and 17e3 are used as the gate electrode, the drain electrode, and the source electrode of the TFT 10D, respectively. The metal layer is formed of a metal film such as aluminum, molybdenum, or tungsten that is 200 nm to 400 nm thick, for example.

Thereafter, by appropriately forming an interlayer insulating film, a pixel electrode, and an alignment film as needed, the TFT substrate 100A can be obtained. Since these forming methods are well known, the descriptions are omitted. The wiring line SE is supplied with a voltage (−2V, for example) that maintains a potential of the light-shielding layer 11 at a constant value to stabilize the properties of the TFD 10A. Also, for the same purpose, it is preferable that an ITO layer (formed of the same ITO film as the pixel electrode, for example) be provided on the insulating layer and the interlayer insulating film that cover the semiconductor layer 13a and that the voltage of the ITO layer be maintained at a constant value (−2V, for example).

Next, a structure of the liquid crystal display device 200 provided with a touch panel function according to the reference example will be explained with reference to FIGS. 5(a) and 5(b). FIG. 5(a) is a schematic plan view of the liquid crystal display device 200, and FIG. 5(b) is a schematic cross-sectional view that shows a TFT substrate 200A of the liquid crystal display device 200. The TFT substrate 200A has an n-channel TFT 20C and a p-channel TFT 20D for a driver circuit of the liquid crystal display device 200, and in FIG. 5(b), cross-sectional structures of the TFTs 20C and 20D are also shown. FIG. 5 corresponds to FIG. 1, and similar constituting elements are given the same reference characters, and the descriptions thereof may be omitted.

As shown in FIGS. 5(a) and 5(b), the TFT substrate 200A of the liquid crystal display device 200 has a substrate 1, a TFD 20A supported by the substrate 1 and including a first semiconductor layer 13a that has a p-type region 13a(p) and an n-type region 13a(n), and a thin film transistor 20B supported by the substrate 1 and having a second semiconductor layer 13b, a gate electrode, a source electrode, and a drain electrode.

The TFT substrate 200A differs from the TFT substrate 100A in that the first wiring line RST and the second wiring line RWS are not disposed so as to overlap with the first semiconductor layer 13a. The first wiring line RST is connected to the p-type region 13a(p) via an electrode 17p, and the second wiring line RWS is connected to the n-type region 13a(n) via an electrode 17n. The electrodes 17p and 17n are formed of the same conductive film (the source metal layer 17 in FIG. 5(b)) as the source electrode and the drain electrode.

As apparent from the comparison between FIGS. 1(a) and 5(a), because the liquid crystal display device 100 according to the embodiment shown in FIG. 1(a) is configured such that the first wiring line RST and the second wiring line RWS overlap with the first semiconductor layer 13a, the proportion of the area occupied by the photosensor section in the pixel P is smaller and the pixel aperture ratio is higher than the liquid crystal display device 200 of the reference example shown in the FIG. 5(a).

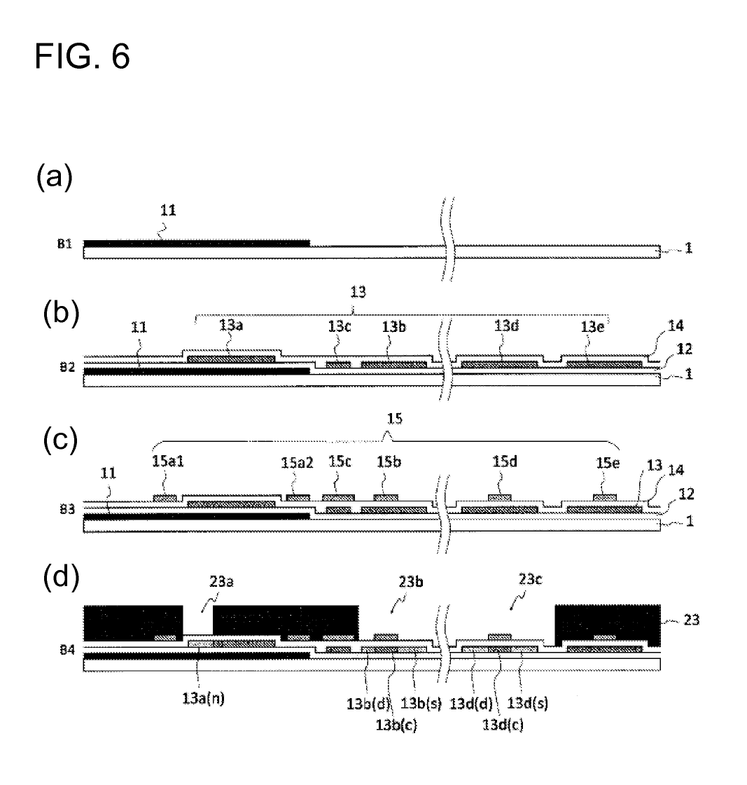

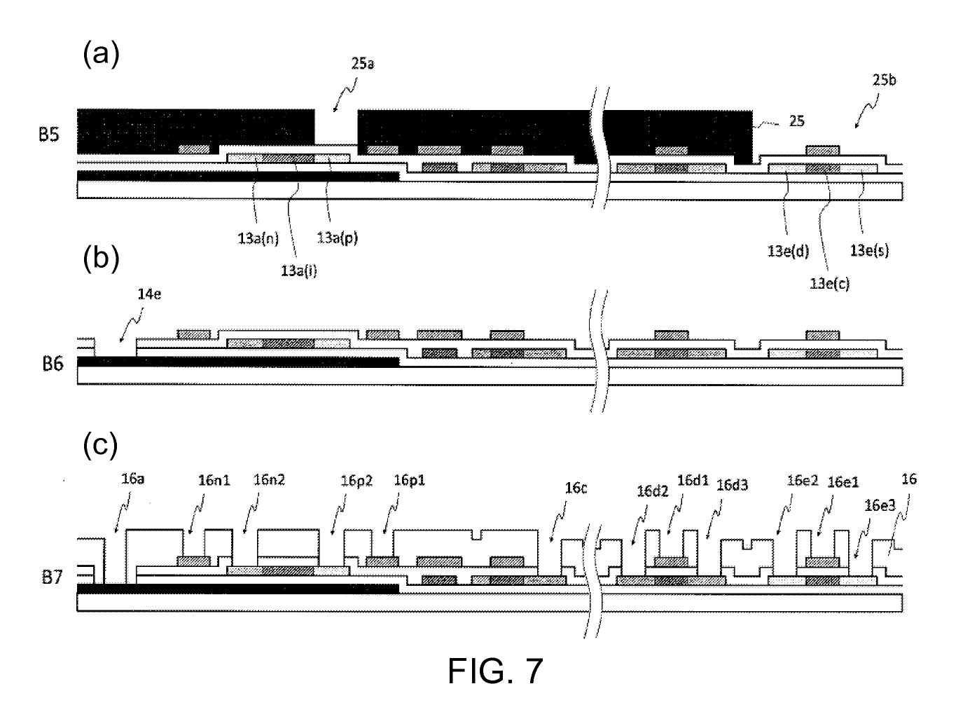

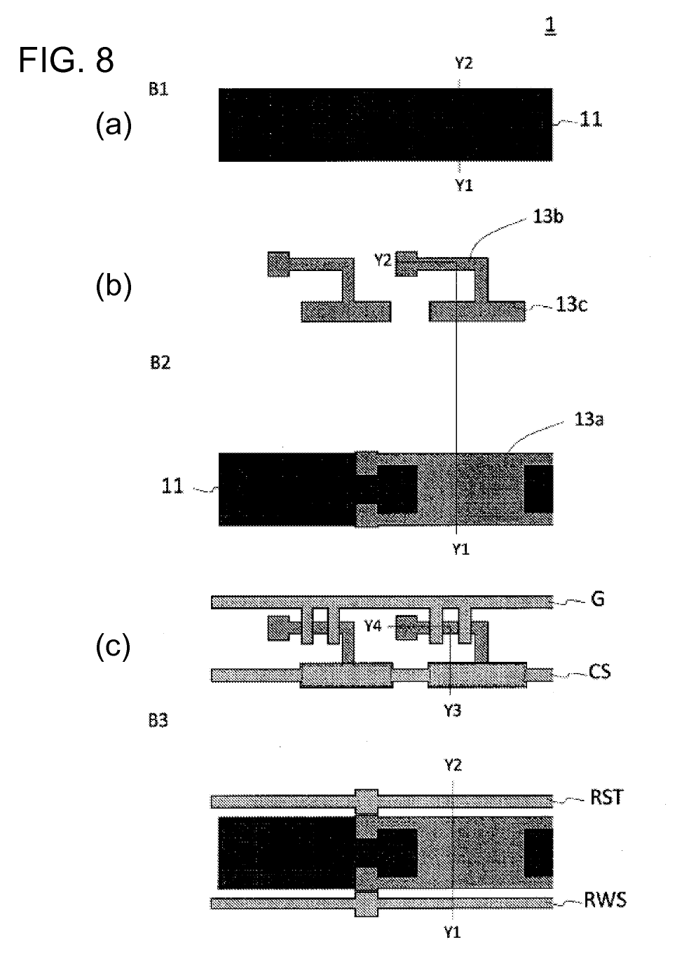

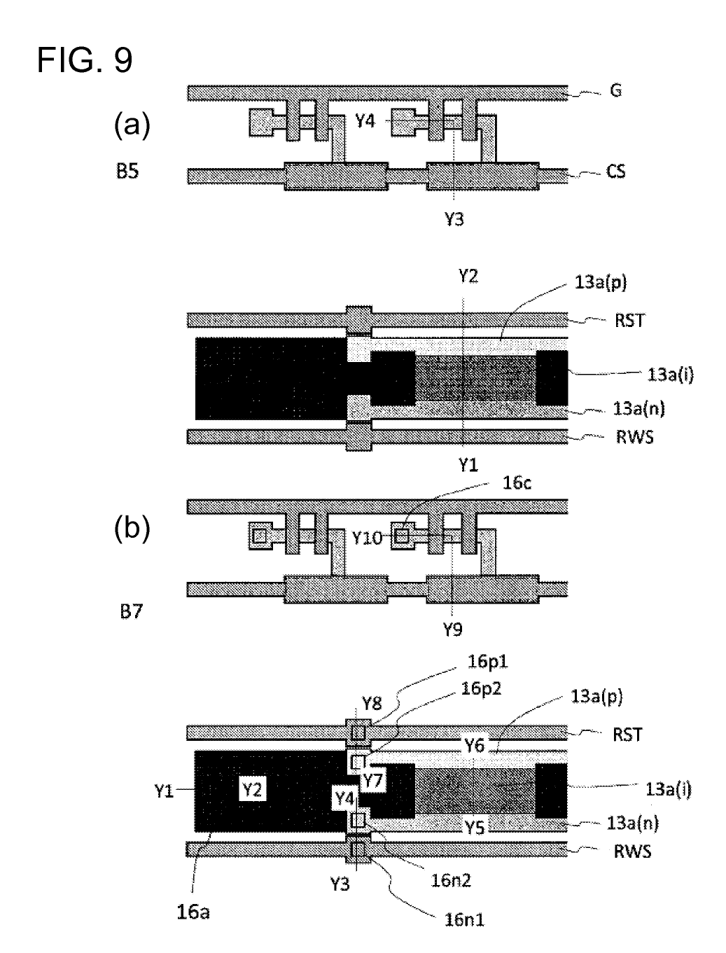

Next, a manufacturing method of the TFT substrate 200A of the reference example will be described with reference to FIGS. 6 to 9. FIGS. 6 and 7 are schematic cross-sectional views, and FIGS. 8 and 9 are schematic plan views. Each cross-sectional view in FIGS. 6 and 7 is a cross-section along the cutoff lines Y1 to Y10 in FIGS. 8 and 9 that correspond thereto, showing a cross-section along the line Y1-Y2, a cross-section along the line Y3-Y4, a cross-section along the line Y5-Y6, a cross-section along the line Y7-Y8, and a cross-section along the line Y9-Y10 in this order from left to right of each cross-sectional view.

The TFT substrate 200A has an n-channel TFT 20C and p-channel TFT 20D for a driver circuit of the liquid crystal display device 200, and in FIGS. 6 and 7, manufacturing processes of the TFTs 20C and 20D are also shown. While the TFD 20A and the TFT 20B are formed within a display region constituted of pixels arranged in a matrix, the TFTs 20C and 20D are formed in a peripheral region (also called a frame region), which is outside of the display region.

First, as shown in FIGS. 6(a) and 8(a), the substrate (a glass substrate, for example) 1 is prepared, and a light-shielding layer 11 is formed over the substrate 1 (step B1). The cross-sectional views of FIG. 5(b) and the following figures show an example in which the light-shielding layer 11 overlaps with the first wiring line RST (15a2) and the second wiring line RWS (15a1) in the end. However, as shown in FIG. 5(a), the light-shielding layer 11 does not necessarily have to overlap with the first wiring line RST (15a2) and the second wiring line RWS (15a1).

Next, as shown in FIGS. 6(b) and 8(b), an insulating film 12 is formed over almost the entire surface of the substrate 1, and after forming semiconductor layers 13 on the insulating film 12, a gate insulating film 14 is formed so as to cover the semiconductor layers 13 (step B2). The semiconductor layers 13 include the semiconductor layer 13a that becomes an active layer of the TFD 20A, the semiconductor layer 13b that becomes an active layer of the TFT 20B, the semiconductor layer 13c that becomes a lower electrode of an auxiliary capacitance of the pixel P, and semiconductor layers 13d and 13e that become active layers of the TFTs 20C and 20D.

Next, as shown in FIGS. 6(c) and 8(c), the gate metal layers 15 including a gate electrode 15b of the TFT 20B are formed (step B3). The gate metal layers 15 include an electrode 15a1 (the second wiring line RWS), an electrode 15a2 (the first wiring line RST), an upper electrode 15c of the auxiliary capacitance, an auxiliary capacitance wiring line CS, a gate electrode 15d of the TFT 20C, and a gate electrode 15e of the TFT 20D. Each of the gate electrodes is formed integrally with a corresponding gate bus line. The electrode 15a1 (the second wiring line RWS) and the electrode 15a2 (the first wiring line RST) are disposed so as not to overlap with semiconductor layer 13a.

Next, as shown in FIG. 6(d), a resist mask 23 having an opening 23a that selectively exposes only a portion of the semiconductor layer 13a that becomes the n-type region 13a(n), an opening 23b that selectively exposes only the semiconductor layer 13b, and an opening 23c that selectively exposes only the semiconductor layer 13d is formed, and thereafter, an n-type impurity (phosphorus, for example) is implanted by ion implantation (step B4). As a result, the n-type region 13a(n) is formed in the semiconductor layer 13a. Also, a drain region 13b(d), a source region 13b(s), and a channel region 13b(c) are formed in the semiconductor layer 13b in a self-aligned manner with respect to the gate electrode 15b, and a drain region 13d(d), a source region 13d(s), and a channel region 13d(c) are formed in the semiconductor layer 13d in a self-aligned manner with respect to the gate electrode 15d.

Subsequently, after removing the resist mask 23, as shown in FIGS. 7(a) and 9(a), a resist mask 25 having an opening 25a that selectively exposes only a portion of the semiconductor layer 13a that becomes the p-type region 13a(p) and an opening 25b that selectively exposes only a semiconductor layer 13e is formed, and thereafter, a p-type impurity (boron, for example) is implanted by ion implantation (step B5). As a result, the p-type region 13a(p) and the intrinsic region 13a(i) are formed in the semiconductor layer 13a. Also, a drain region 13e(d), a source region 13e(s), and a channel region 13e(c) are formed in the semiconductor layer 13e in a self-aligned manner with respect to the gate electrode 15e.

Next, after removing the resist mask 25, as shown in FIG. 7(b), a contact hole 14e that exposes the light-shielding layer 11 is formed in the gate insulating film 14 and the insulating film 12 (step B6).

Next, as shown in FIGS. 7(c) and 9(b), an insulating film 16 that covers almost the entire surface of the substrate 1 is formed, and contact holes 16a, 16n1, 16n2, 16p1, 16p2, 16c, 16d1, 16d2, 16d3, 16e1, 16e2, and 16e3 are formed (step B7).

Thereafter, by patterning a metal film formed over almost the entire surface of the substrate 1, as shown in FIGS. 5(a) and 5(b), the TFD 20A, the TFT 20B, the TFT 20C, and the TFT 20D are formed in the TFT substrate 200A. A metal layer 17a is used as the wiring line SE that is connected to an electrode 15s through the contact hole 16a. A metal layer 17f is used as the source bus line S that is connected to the source electrode of the TFT 20B of an adjacent pixel. A metal layer 17n connects the second wiring line RWS and the n-type region 13a(n) to each other, and a metal layer 17p connects the first wiring line RST and the p-type region 13a(p) to each other. A metal layer 17c is used as the source electrode of the TFT 20B. Metal layers 17d1, 17d2, and 17d3 are used as the gate electrode, the drain electrode, and the source electrode of the TFT 20C, respectively. Metal layers 17e1, 17e2, and 17e3 are used as the gate electrode, the drain electrode, and the source electrode of the TFT 20D, respectively.

As understood by the above descriptions, the TFT substrate 200A of the liquid crystal display device 200 of the reference example can be manufactured with fewer steps than the TFT substrate 100A. Therefore, when manufacturing cost is more important than the pixel aperture ratio, the structure and the manufacturing method of the reference example may be used.

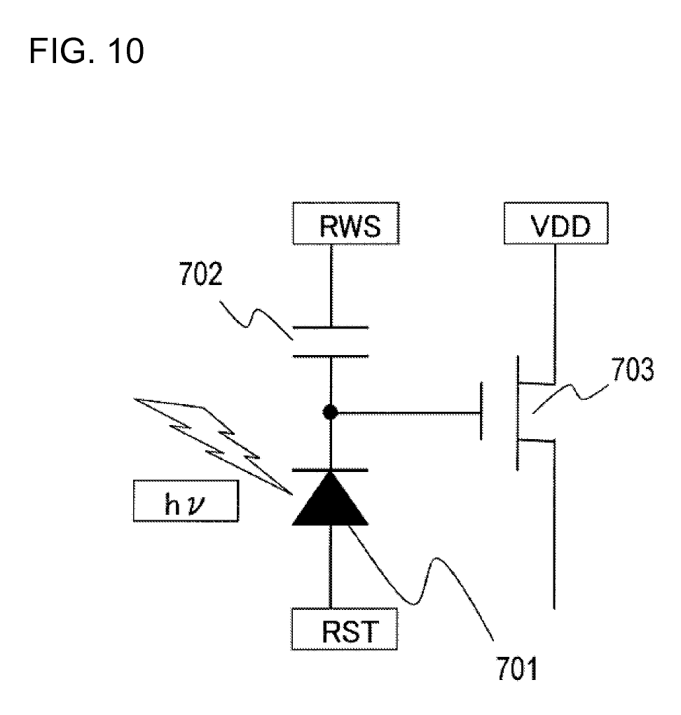

Next, a configuration and an operation of the photosensor section of the liquid crystal display device 100 will be explained with reference to FIG. 10.

As shown in FIG. 10, the photosensor section has a TFD 701, a capacitor for signal storage 702, and a thin film transistor for signal readout 703. The TFD 701 has a structure similar to the TFD 10A described above, for example. The capacitor for signal storage 702 (not shown in FIG. 1) uses a gate electrode layer and a semiconductor layer as electrodes thereof, and the capacitance thereof can be formed by a gate insulating film.

A p-type region of the TFD 701 is connected to a RST signal line, and an n-type region is connected to a lower electrode (Si layer) of the capacitor for signal storage and to an RWS signal line via the capacitor. Furthermore, the n-type region is connected to the gate electrode layer of the thin film transistor for signal readout 703. The source region of the thin film transistor for signal readout 703 is connected to a VDD signal line, and the drain region is connected to a signal output line. These signal lines double as the source bus lines.

Next, the operation of the photosensor section in sensing light will be explained.

(1) First, an RST signal is inputted from the RST signal line. As a result, a positive voltage is applied to the p-type region side of the photosensor TFD 701, making the TFD 701 forward-biased, and electric charges of the capacitor 702 are discharged. Thereafter, when the RST signal is turned off, the TFD 701 becomes reverse-biased.

(2) When a photocurrent is generated in the TFD 701, the capacitor for signal storage 702 is charged via the TFD 701.

(3) As a result, the potential of the n-type region side of the TFD 701 is reduced, and this potential variation changes the gate voltage applied to the thin film transistor for signal readout 703.

(4) A VDD signal from the VDD signal line is applied to the source side of the thin film transistor for signal readout 703. As described above, when the gate voltage changes, a value of current flowing into the output signal line connected to the drain side is changed, and therefore, it is possible to read out the electrical signal from the output signal line.

The photo sensing can be performed by repeating the above-mentioned operations (1) to (4) while conducting scanning.

The structure of the TFT is not limited to the example described above, and the n-channel type and the p-channel type may be reversed. Furthermore, in the above description, the double gate structure was illustrated, but the TFT structure may be a single gate structure. Also, an LLD structure or a GOLD structure may be applied. The semiconductor layer is not limited to a polysilicon layer and a CG silicon layer, and an oxide semiconductor layer may be used. The structures of the respective layers constituting the TFD and the TFT are not limited to the single layer structure illustrated above, and a multilayer structure may also be employed.

### Industrial Applicability

The present invention can be widely applied to a semiconductor device provided with a photosensor section that uses the TFD, or electronic devices in various fields that have such a semiconductor device. The present invention may be applied to an active matrix-type liquid crystal display device or an organic EL display device, for example. Such display devices can be used for display screens of mobile telephones or mobile gaming devices, monitors of digital cameras, and the like, for example. Therefore, the present invention is applicable to all electronic devices with a liquid crystal display device or an organic EL display device built therein.

In particular, the present invention can be suitably used for display devices such as an active matrix-type liquid crystal display device or an organic EL display device, image sensors, photosensors, and electronic devices obtained by combining them. It is especially advantageous to apply the present invention to a display device with photosensor function that uses a TFD such as a display device that has both a touch panel function and a scanner function.

### DESCRIPTIONS OF REFERENCE CHARACTERS

1 substrate

10A thin film diode

10B thin film transistor

11 light-shielding layer

12 insulating film

13a, 13b semiconductor layer

13a(p) p-type region

13a(n) n-type region

13a(i) intrinsic region

14 gate insulating film

15 conductive layer (gate metal layer)

16 insulating film

17 metal layer (source metal layer)

RST first wiring line

RWS second wiring line

100 semiconductor device (liquid crystal display device)

100A TFT substrate

1. A semiconductor device, comprising:
a substrate;
a thin film diode supported by the substrate, the thin film diode including a first semiconductor layer that has a p-type region and an n-type region;
a first wiring line disposed so as to overlap with the first semiconductor layer of the thin film diode, the first wiring line being connected to the p-type region;
a second wiring line disposed so as to overlap with the first semiconductor layer of the thin film diode, the second wiring line being connected to the n-type region; and
a thin film transistor supported by the substrate, the thin film transistor including a second semiconductor layer, a gate electrode, a source electrode, and a drain electrode,
wherein the first wiring line and the second wiring line are formed of a same conductive film as the gate electrode.

2. The semiconductor device according to claim 1, wherein the first semiconductor layer and the second semiconductor layer are formed of a same semiconductor film.

3. The semiconductor device according to claim 1, wherein the gate electrode is formed above the second semiconductor layer.

4. A method of manufacturing a semiconductor device, comprising:
(a) preparing a substrate;
(b) forming a first semiconductor layer and a second semiconductor layer on the substrate;
(c) forming an insulating layer that covers the first semiconductor layer and the second semiconductor layer;
(d) implanting an impurity into the first semiconductor layer to form a p-type region and an n-type region;
(e) forming a contact hole in the insulating layer;
(f) forming, after the step (e), a conductive layer including a first wiring line connected to the p-type region, a second wiring line connected to the n-type region, and a gate electrode on the insulating layer; and
(g) forming, after the step (f), a source region and a drain region in the second semiconductor layer.

5. The method of manufacturing a semiconductor device according to claim 4, wherein, in the step (b), the first semiconductor layer and the second semiconductor layer are formed of a same semiconductor film.
